(19) United States
(12) Patent Application Publication
(10) Pub. No.: US 2010/0184244 A1
(43) Pub. Date: Jul. 22, 2010

(54) SYSTEMS AND METHODS FOR DEPOSITING PATTERNED MATERIALS FOR SOLAR PANEL PRODUCTION

(75) Inventor: Thomas Peter Hunt, Oakland, CA (US)

Correspondence Address: JONES DAY, 222 EAST 41ST ST, NEW YORK, NY, 10017, US

(73) Assignee: SunPrint, Inc., Richmond, CA (US)

(21) Appl. No.: 12/689,822

(22) Filed: Jan. 19, 2010

Related U.S. Application Data
(60) Provisional application No. 61/205,545, filed on Jan. 20, 2009.

(51) Int. Cl. H01L 31/18; H01L 21/04

(52) U.S. Cl. 438/57; 438/478; 118/665; 438/680; 438/694; 257/E31.032; 438/669; 257/E21.04; 257/E31.001

(57) ABSTRACT

Method and system for forming one or more predetermined patterns on a substrate for making a photovoltaic device. The method includes aligning at least a first droplet source with a substrate, dispensing one or more first droplets associated with one or more first materials from the first droplet source, and forming at least a first pattern of one or more second materials on the substrate by at least the first droplet source. Additionally, the method includes providing a first light beam incident on at least the first pattern, obtaining a first signal associated with the first pattern in response to the first light beam, processing information associated with the first signal, and determining one or more first characteristics of the first pattern based on at least information associated with the first signal.

### 1. CROSS-REFERENCES TO RELATED APPLICATIONS

This application claims priority to U.S. Provisional No. 61/205,545, filed Jan. 20, 2009, commonly assigned, incorporated by reference herein for all purposes.

Additionally, this application is related to U.S. patent application Ser. No. 12/329,325, commonly assigned, incorporated by reference herein for all purposes.

### 2. BACKGROUND OF THE INVENTION

The present invention is directed to material deposition. More particularly, the invention provides systems and methods for depositing material with predetermined characteristics. Merely by way of example, the invention has been applied to making photovoltaic devices. But it would be recognized that the invention has a much broader range of applicability.

Photovoltaics convert sunlight into electricity, providing a desirable source of clean energy. Some examples of current commercial photovoltaic solar cells are made of crystalline silicon and thin film (CdTe (Cadmium Telluride), CIGS (Copper-Indium-Gallium-Diselenide), or amorphous silicon) as well as polymer (P3HT/PCBM (poly(3-hexylthiophene)/phenyl-C61-butyric acid methyl ester) and derivatives).

However, the production of photovoltaics is limited by the high cost of fabricating such devices. Conventional manufacturing techniques for thin film photovoltaic devices are expensive. Most of these techniques require vacuum environments which drastically increase the capital cost, maintenance cost, and material cost required to manufacture thin film photovoltaic devices. Examples of such conventional manufacturing techniques are: Plasma Enhanced Chemical Vapor Deposition (PECVD), Chemical Vapor Deposition (CVD), Closed Space Sublimation (CSS), and Vapor Transport Deposition (VTD). Furthermore, these conventional techniques generally have very poor material use efficiency, as they often deposit material non-specifically inside a deposition chamber, thereby significantly increasing the total cost of the photovoltaic module. In addition, as these methods usually deposit material over the entire substrate, the layers often need subsequent partitioning or scribing into a series of interconnected cells to produce a photovoltaic module. Partitioning or scribing is relatively slow, expensive, prone to yield problems, and wasteful of the material between cells and near the module edges.

On the other hand, many printing techniques exist, yet each has its own drawbacks for the manufacture of thin film photovoltaic modules. For example, conventional screen printing can be low cost, but often is difficult to align precisely over large areas, and can result in layers with a minimum thickness of 10 microns (high material use), with poor resultant layer uniformity, which is unsuitable for some layers in solar modules or cells. Conventional roll-to-roll printing or roller printing (such as gravure or off-set printing) is often difficult to adapt to stiff substrates, such as glass, that may be desirable for use in solar modules, and pattern edges typically have poor thickness uniformity. In addition, the contact of roll-to-roll or roller printing can damage previously patterned layers. A non-contact method of material deposition is needed for the manufacture of thin film solar modules or cells.

Several non-contact material deposition methods exist, but they have some significant limitations for thin film solar cell production. For example, spray deposition produces films at high throughput and low cost, but has poor edge definition and film uniformity problems. Inkjet techniques can suffer from nozzle clogging and drop placement accuracy. Lack of drop placement accuracy decreases film uniformity, or even creating voids in the film or depositing material in the incorrect location, thereby in some cases destroying the photovoltaic device, or severely limiting its efficiency, and drastically lowering device yield. Inkjet nozzle clogging has a similar effect, maybe causing voids in the material layers of the photovoltaic cell. Even if nozzles do not become completely clogged, partial clogging can drastically affect the size of ejected droplets and hence the thickness of the resulting film.

Hence it is highly desirable to improve fabrication techniques for photovoltaic devices.

### 3. BRIEF SUMMARY OF THE INVENTION

The present invention is directed to material deposition. More particularly, the invention provides systems and methods for depositing material with predetermined characteristics. Merely by way of example, the invention has been applied to making photovoltaic devices. But it would be recognized that the invention has a much broader range of applicability.

According to one embodiment, a method for forming one or more predetermined patterns on a substrate for making a photovoltaic device is provided. The method includes aligning at least a first droplet source with a substrate, dispensing one or more first droplets associated with one or more first materials from the first droplet source, and forming at least a first pattern of one or more second materials on the substrate by at least the first droplet source. Additionally, the method includes providing a first light beam incident on at least the first pattern, obtaining a first signal associated with the first pattern in response to the first light beam, processing information associated with the first signal, and determining one or more first characteristics of the first pattern based on at least information associated with the first signal. Moreover, the method includes processing information associated with the one or more first characteristics, and changing the first pattern to a second pattern by at least a pattern forming device. The pattern forming device including at least a second droplet source, at least a material removal device, or at least the second droplet source and the material removal device.

According to another embodiment, a method for forming one or more predetermined patterns on a substrate for making a photovoltaic device is provided. The method includes aligning at least a first droplet source with a substrate, dispensing one or more droplets associated with one or more first materials from the first droplet source, and forming at least a first pattern of one or more second materials on the substrate by at least the first droplet source. Additionally, the method includes providing a light beam incident on at least the one or more droplets, obtaining a signal associated with the one or more droplets in response to the light beam, processing information associated with the signal, and determining one or more characteristics of the first pattern based on at least information associated with the signal. Moreover, the method includes processing information associated with the one or more characteristics, and changing the first pattern to a second pattern by a pattern forming device. The pattern forming device includes at least a second droplet source, at least a material removal device, or at least the second droplet source and the material removal device.

According to yet another embodiment, a system for forming one or more predetermined patterns on a substrate for making a photovoltaic device is provided. The system includes a positioning system configured to align at least a first droplet source with a substrate, at least the first droplet source configured to dispense one or more first droplets associated with one or more first materials and form at least a first pattern of one or more second materials on the substrate, and a light source configured to provide a first light beam incident on at least the first pattern. Additionally, the system includes a sensing device configured to obtain a first signal associated with the first pattern in response to the first light beam, and a control device configured to receive the first signal, process information associated with the first signal, determine one or more first characteristics of the first pattern based on at least information associated with the first signal, process information associated with the one or more first characteristics, and output a second signal based on at least information associated with the one or more first characteristics. Moreover, the system includes at least a first pattern forming device configured to receive the second signal and change the first pattern to a second pattern based on at least information associated with the second signal. The first pattern forming device includes at least a second droplet source, at least a material removal device, or at least the second droplet source and the material removal device.

According to yet another embodiment, a system for forming one or more predetermined patterns on a substrate for making a photovoltaic device is provided. The system includes a positioning system configured to align at least a first droplet source with a substrate, at least the first droplet source configured to dispense one or more droplets associated with one or more first materials and form at least a first pattern of one or more second materials on the substrate, and a light source configured to provide a light beam incident on at least the one or more droplets. Additionally, the system includes a sensing device configured to obtain a first signal associated with the first pattern in response to the light beam, and a control device configured to receive the first signal, process information associated with the first signal, determine one or more characteristics of the first pattern based on at least information associated with the first signal, process information associated with the one or more characteristics, and output a second signal based on at least information associated with the one or more characteristics. Moreover, the system includes at least a pattern forming device configured to change the first pattern to a second pattern. The pattern forming device including at least a second droplet source, at least a material removal device, or at least the second droplet source and the material removal device.

Many benefits are achieved by way of the present invention over conventional techniques. Certain embodiments of the present invention can improve film uniformity and/or edge definition in thin films for photovoltaic modules. Some embodiments of the present invention can improve material patterns for photovoltaic modules and/or cells. Certain embodiments of the present invention implement an optical feedback system to detect and correct film patterns that are miss-located, too thick, or too thin. Some embodiments of the present invention provide a printing technology that is capable of fabricating low-cost, high-performance solar cells. Certain embodiments of the present invention can reduce film defects. Some embodiments of the present invention can improve throughput which is important, for example, to thin film solar manufacturing processes.

Depending upon embodiment, one or more of these benefits may be achieved. These benefits and various additional objects, features and advantages of the present invention can be fully appreciated with reference to the detailed description and accompanying drawings that follow.

### 4. BRIEF DESCRIPTION OF THE DRAWINGS

FIG. 1 is a simplified diagram showing a method for depositing one or more materials for photovoltaic cells according to one embodiment of the present invention.

FIG. 2 is a simplified diagram showing a system for depositing one or more materials for photovoltaic cells according to one embodiment of the present invention.

FIGS. 3A, 3B, and 3C are simplified diagrams showing the deposition/removal units and the feedback system as parts of the system for depositing one or more materials for photovoltaic cells according to certain embodiments of the present invention.

FIGS. 4A, 4B, 4C, 4D, 4E, and 4F are simplified diagrams showing the deposition/removal units as parts of the system for depositing one or more materials for photovoltaic cells according to certain embodiments of the present invention.

FIGS. 5A, 5B, 5C, 5D, 5E, 5F, and 5G are simplified diagrams showing one or more layers of one or more materials that formed by the system 200 for depositing one or more materials for photovoltaic cells according to certain embodiments of the present invention.

FIG. 6 is a simplified diagram showing a method for manufacturing a photovoltaic device according to one embodiment of the present invention.

### 5. DETAILED DESCRIPTION OF THE INVENTION

The present invention is directed to material deposition. More particularly, the invention provides systems and methods for depositing material with predetermined characteristics. Merely by way of example, the invention has been applied to making photovoltaic devices. But it would be recognized that the invention has a much broader range of applicability.

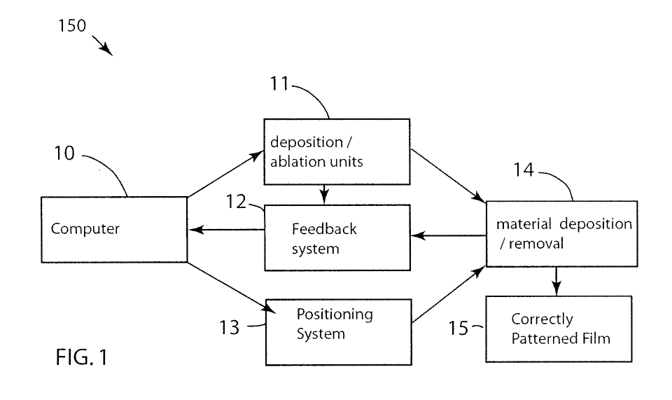

FIG. 1 is a simplified diagram showing a method for depositing one or more materials for photovoltaic cells according to one embodiment of the present invention. This diagram is merely an example, which should not unduly limit the scope of the claims. One of ordinary skill in the art would recognize many variations, alternatives, and modifications.

For example, the method 150 as shown in FIG. 1 deposits the one or more materials with or without predetermined patterns. In another example, the method 150 uses a feedback to detect film defects, and/or uses one or more deposition and/or removal processes to repair these defects. According to one embodiment, a removal process includes an ablation process. According to another embodiment, these defects may be composed of holes in a film, film deposition in an incorrect area, imperfections in film edge, film thickness variation, and/or others.

In yet another example, the final resulting films formed according to the method 150 have predetermined electrical properties such as high or low electrical resistance, semiconductor properties, and/or photovoltaic properties. In yet another example, the final resulting films formed according to the method 150 have predetermined optical properties, such as being transparent, transparent to certain wavelengths of light, opaque, or reflective. In yet another example, the final resulting films formed according to the method 150 are used in photovoltaic devices, such as solar cells.

As shown in FIG. 1, the method 150 utilizes a computer 10, one or more deposition/removal units 11, a positioning system 13, and a feedback system 12 according to an embodiment of the present invention. For example, the one or more deposition/removal units include a deposition printhead and/or an ablation device. In another example, the positioning system 13 is configured to adjust the relative position between the one or more deposition/removal units 11 and the substrate on which the one or more materials are deposited.

According to certain embodiments, the computer 10 controls the deposition/removal units 11 as well as the positioning system 13. For example, the computer 10 sends one or more commands to the deposition/removal units 11, and in response, the deposition/removal units perform one or more material deposition/removal processes 14. According to one embodiment, the one or more deposition/removal processes 14 are used to print one or more patterned material layers, each of which is precisely registered to the substrate or previous layers, of precisely controlled shape, thickness, and/or composition.

For example, the computer 10 sends one or more commands to the deposition/removal units 11 to print one or more materials onto the substrate and/or ablate the deposited materials from the substrate, so that the resulting film 15 has a pattern that is precisely registered to the substrate or previous layers, of precisely controlled shape, thickness, and composition. In another example, the feedback system 12 provides one or more control feedback information to the computer 10 based on feedback data that are indicative of one or more monitored characteristics of the deposited film, and/or one or more monitored characteristics of the deposition/removal units 11. According to one embodiment, these characteristics are monitored by optical transmission determination through the deposited film, optical clogged nozzle detection, optical droplet path monitoring, film edge analysis, ablation power readout, ablation laser focusing, and/or mechanical ablation location.

As shown in FIG. 1, closing the feedback loop with data from the feedback system 12, the computer 10 sends one or more commands to the deposition/removal units 11 to improve the deposited film, for example, by filling in pinholes, ablating film material in the incorrect location, or meeting film thickness setpoint by the addition or removal of material from some of the deposition/removal units 11. One or more cycles through the feedback loop of deposition/removal, sensing, and calculated correction can be used to fabricate a correctly patterned film 15 according to certain embodiments of the present invention.

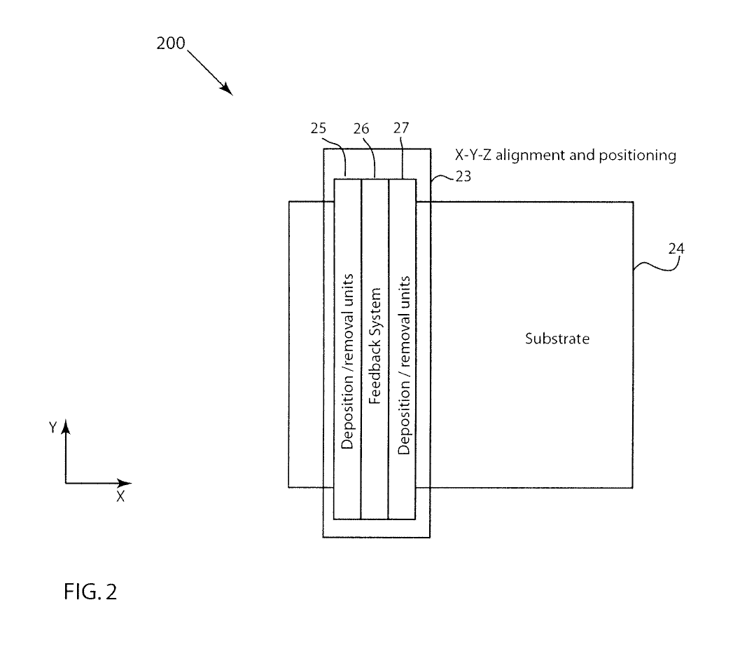

FIG. 2 is a simplified diagram showing a system for depositing one or more materials for photovoltaic cells according to one embodiment of the present invention. This diagram is merely an example, which should not unduly limit the scope of the claims. One of ordinary skill in the art would recognize many variations, alternatives, and modifications.

For example, the system 200 is a printing, ablation, and feedback system that can be used to pattern one or more films onto a substrate to produce photovoltaic solar cells. In another example, the system 200 is configured to perform the method 150. In yet another example, the system 200 includes one or more deposition/removal units 25, a feedback system 26, one or more deposition/removal units 27, and an XY-Z alignment and positioning system 23.

According to one embodiment, the deposition/removal units 25, and/or the deposition/removal units 27 are part of the one or more deposition/removal units 11. According to another embodiment, the X-Y-Z alignment and positioning system 23 is the positioning system 13. According to yet another embodiment, the feedback system 26 is the feedback system 12.

As shown in FIG. 2, a substrate 24 is positioned relative to the deposition/removal units 25 and 27 and the feedback system 26 in X, Y, and Z directions by the alignment and positioning system 23. For example, the positioning system 23 can control the relative position of the deposition/removal units 25 with respect to the substrate 24 within 10 microns or within 1 micron in X and Y directions, and/or within 50 microns or within 5 microns in the Z direction.

In one embodiment, as the substrate 24 is positioned relative to the deposition/removal units 25 and 27, the units 25 and/or 27 deposit a patterned film on the substrate as shown in FIG. 2. Imperfections in the film, such as voids, deposition in undesired locations, thickness or other material property variations, are detected by the feedback system. In response, the deposition/removal units 25 and/or 27 then take appropriate measures to improve the film, for example, by depositing material in voids, ablating material in undesired locations, and depositing and/or ablating material to meet thickness or other property setpoints. As shown in FIG. 2, two sets 25 and 27 of aligned deposition/removal units allow for deposition/removal, feedback, and film error correction to occur at high speed on an inline process with one pass of the substrate relative to the deposition/removal units 25 and 27.

As discussed above and further emphasized here, FIG. 2 is merely an example, which should not unduly limit the scope of the claims. One of ordinary skill in the art would recognize many variations, alternatives, and modifications. For example, the system 200 includes the deposition/removal units 25, but not the deposition/removal units 27. In another example, one of the deposition/removal units 25 includes a deposition component, a removal component, or both a deposition component and a removal component. In yet another example, one of the deposition/removal units 27 includes a deposition component, a removal component, or both a deposition component and a removal component.

In one embodiment, the system 200 also works for multiple-pass printing. In multiple-pass printing, for example, the deposition/removal units 25 produce a pattern as the units 25 move relative to the substrate 24. Subsequently, the deposition/removal units 25 are re-positioned by the positioning system 23, and the units 25 can once again move relative to the substrate, producing another pattern either overlapping or in proximity to the previous pattern. The two overlapping patterns can improve uniformity and reduce defects according to an embodiment. For example if one of the units 25, such as a printhead, includes a plurality of nozzles and only some of these nozzles perform identically, forming overlapping patterns with different sets of nozzles can reduced the impact of differing nozzles on film quality. In one embodiment, a set of nozzles of a printhead is used to print a predetermined pattern, and then another set of nozzles is used to repeat the same predetermined pattern. In the event that a few nozzles are not functioning, a pattern that has been repeated with two independent sets of nozzles can be much closer to the desired pattern than a pattern that has only been deposited by a single set of nozzles according to an embodiment of the present invention.

Returning to FIG. 2, the feedback system 26 is configured to perform at least optical film characterization according to certain embodiments of the present invention. For example, the transmission or reflection from a LED or laser at a certain wavelength is detected by a CCD or photodiode array as part of the feedback system 26. In another example, thickness monitors as part of the feedback system 26 are used to ensure uniform coatings across the width of the solar cell on the substrate 24. In yet another example, the feedback system 26 is configured to perform optical monitoring of the deposition/removal units 25 according to some embodiments of the present invention. For example, nozzle clogging, droplet or spray path, and/or throughput are detected and/or characterized by the feedback system 26. In another example, a pinhole or electrical short detection system as part of the feedback system 26 records the position of undesired features in the films. In yet another example, optical and temperature readouts from the feedback system 26 can be used to correct for temperature drift. According to certain embodiments, the feedback system 26 is configured to characterize the performance of the sub-cells on the solar panel, remap the electrical connections, and/or print an optimized configuration of series and parallel connections between the solar cells during a later printing and processing step in order to improve panel performance.

As shown in FIG. 2, the deposition/removal units 25 and/or 27 are suited for patterned photovoltaic material deposition according to certain embodiments of the present invention. For example, one of the units 25 and/or 27 includes a deposition printhead and/or an ablation device. In one embodiment, the deposition printhead includes a plurality of inkjet nozzles, focused acoustic ejectors, and/or spray nozzles arranged to provide continuous droplet coverage over the width or length of a desired material film. In another embodiment, the printheads of the units 25 and/or 27 faun one or more arrays of droplet sources. These printheads can be sized and arranged to produce one or more films of one or more materials that correlate to the exact width of a thin film photovoltaic cell. For example, the length of the cell is determined by the movement of either the printheads or the movement of the substrate 24. In another example, the droplet sources that make up one or more printheads are spaced apart from one another such that each solar cell is electrically isolated from its next solar cell.

As discussed above, one of the units 25 and/or 27 includes an ablation device according to some embodiments. For example, the ablation device is optimized for patterned photovoltaic material removal. In another example, the ablation device includes an optical ablation component and/or a mechanical ablation component, such as a laser, a laser beam path, focusing optics, a high speed saw, a abrasive wheel, a diamond point, etc.

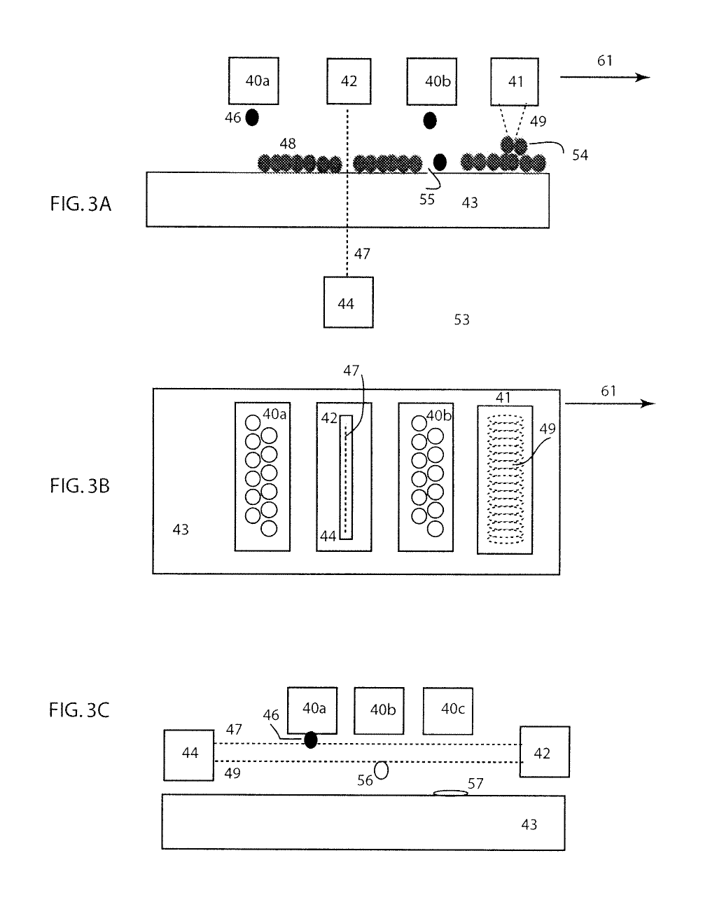

FIGS. 3A, 3B, and 3C are simplified diagrams showing the deposition/removal units 25 and/or 27 and the feedback system 26 as parts of the system 200 for depositing one or more materials for photovoltaic cells according to certain embodiments of the present invention. These diagrams are merely examples, which should not unduly limit the scope of the claims. One of ordinary skill in the art would recognize many variations, alternatives, and modifications.

For example, the deposition/removal units 25 and/or 27 and the feedback system 26 as shown in each of FIGS. 3A, 3B, and 3C are capable of detecting and correcting film defects. In another example, the deposition/removal units 25 and/or 27 and the feedback system 26 as shown in each of FIGS. 3A, 3B, and 3C are capable of depositing and ablating material to form patterned films, reading out the properties of these films, and correcting the properties of these films with additional deposition or ablation according to various embodiments of the present invention. For example, the deposition/removal units 25 and/or 27 each include one or more droplet sources 40. In one embodiment, a printhead includes one or more droplet sources 40. In another embodiment, one of the droplet sources 40 includes one or more focused acoustic ejectors, one or more inkjet nozzles, and/or one or more spray nozzles. For example, the droplet sources 40 are positioned slightly staggered from each other so as to provide a single pass, raster-free (if so desired) method of printing the desired pattern on a substrate. In another example, the deposition/removal units 25 and/or 27 move relative to a substrate 43 in the direction of 61 as shown in FIGS. 3A, 3B, and 3C. In one embodiment, the substrate 43 is the substrate 24.

FIGS. 3A and 3B are simplified side view and top view respectively for the deposition/removal units 25 and/or 27 and the feedback system 26 as parts of the system 200 for depositing one or more materials for photovoltaic cells according to one embodiment of the present invention. These diagrams are merely examples, which should not unduly limit the scope of the claims. One of ordinary skill in the art would recognize many variations, alternatives, and modifications.

According to one embodiment, a droplet source 40a produces one or more droplets 46 that form a film 48 on the substrate 43. For example, the droplet source 40a is part of one of the deposition/removal units 25, and this one of the deposition/removal units 25 includes or does not include a removal component. In another example, the substrate 43 is the substrate 24. As shown in FIGS. 3A and 3B, the feedback system 26 includes a light source 44 and a detector 42, which are located on opposite sides of the substrate 43. In another embodiment, the light source 44 and the detector 42 are located on the same side of the substrate 43.

For example, the light source is configured to shine a beam of light 47 through the substrate 43 to a detector 42. In another example, the light source 44 includes a laser, a lamp, and/or a LED. In yet another example, the light source 44 provides the light 47 that is monochromatic for measuring absorption, transmission, or reflection at one wavelength, or have two or more different wavelengths on the same or offset beam paths for differential measurements. In yet another example, the detector 42 includes one or more photodiodes, one or more photomultipliers, one or more linear CCD arrays, and/or one or more 2-dimensional CCD arrays with or without an imaging lens system.

According to one embodiment, the light source 44 and the detector 42 are configured to obtain various characteristics of the film 48, such as absorption, transmission, reflection, roughness, fluorescence, and/or film imaging. According to another embodiment, the light source 44 and the detector 42 are configured to perform optical/electrical measurements with appropriate electrical equipment. For example, the optical/electrical measurements include photovoltaic IV curves and/or photoemission.

The feedback system 26 that includes the light source 44 and the detector 42 is configured to detect excessively thick film area 54, excessively thin film area 55, and/or other defects or misalignment in the film 48. As shown in FIGS. 3A and 3B, depending on the readout from the detector 42, a droplet source 40b or an ablation device 41 can be triggered to deposit or ablate material and achieve the desired film properties. In one embodiment, the droplet source 40b and the ablation device 41 are parts of one of the deposition/removal units 27. In another embodiment, the ablation device 41 includes a laser scriber that removes film material with a high intensity laser pulse 49. As shown in FIGS. 3A and 3B, the ablation device 41 is configured to provide ablation at any point along the width of the droplet source 40b, or just at the selected locations of the film 48.

FIG. 3C is a simplified side view for the deposition/removal units 25 and/or 27 and the feedback system 26 as parts of the system 200 for depositing one or more materials for photovoltaic cells according to one embodiment of the present invention. These diagrams are merely examples, which should not unduly limit the scope of the claims. One of ordinary skill in the art would recognize many variations, alternatives, and modifications. For example, one or more ablation devices can be added to the system 200.

As shown in FIG. 3C, a light source 44 sends a beam of light 47 to a detector 42. For example, the detector 42 is configured to determine the size, position, and timing of each of one or more droplets 46 that are produced by a droplet source 40a. In another example, the detector 42 includes one or more photodiodes, one or more photomultipliers, one or more linear CCD arrays, and/or one or more 2-dimensional CCD arrays with or without an imaging lens system.

In one embodiment, the feedback system 26 is configured to detect clogging or other problems with the droplet source 40a, and make immediate corrections to redundant droplet sources 40b and 40c. In another embodiment, the light source 44 is configured to provide a laser beam 49, such as a powerful CW or pulsed laser beam 49 that is capable of changing the properties of one or more droplets 56 before the droplets impinge on the substrate 43. For example, none or at least some of the one or more droplets 46 is part of the one or more droplets 56. In another example, none or at least some of the one or more droplet 56 is part of the one or more droplets 46.

In one embodiment, the one or more droplets 56 are produced by the droplet source 40a, the droplet source 40b, and/or the droplet source 40c. In another embodiment, the laser beam 49 can be triggered or steered to the correct location by signals from the detector 42. In yet another embodiment, the laser beam 49 raises the temperature of the one or more droplets 56, evaporate the solvent in the one or more droplets 56, melt solid material in one or more droplets 56, and/or vaporize all of the material in the one or more droplets 56.

According to one embodiment, the changes induced in the one or more droplets 56 by the laser beam 49 are favorable for the formation of a film of material 57 from the one or more droplets 56. For example, by superheating the material in the one or more droplets 56, the droplets 56 become more conforming to the substrate 43, or can produce crystals with desirable properties for materials used in solar panels. According to another embodiment, changing the temperature or phase of one or more components of the one or more droplets 56 result in improved material deposition for materials used in solar panels. According to yet another embodiment, vaporizing the contents of the one or more droplets 56 close to the substrate 43 allows for localized vapor deposition rather than deposition of discrete particles. For example, vapor deposited films have superior properties for materials used in solar panels. According to yet another embodiment, locally heating the one or more droplets 56 allows the use of the substrate 43 that does not need to be heated to as high of a temperature as would be otherwise be needed for high quality film formation, especially important for high melting point semiconductor materials.

As shown in FIGS. 2 and 3C, each of the droplet sources 40a, 40b, and 40c is part of one of the deposition/removal units 25 or 27, and this one of the deposition/removal units 25 or 27 includes or does not include a removal component according to some embodiments. In certain embodiments, the substrate 43 is the substrate 24.

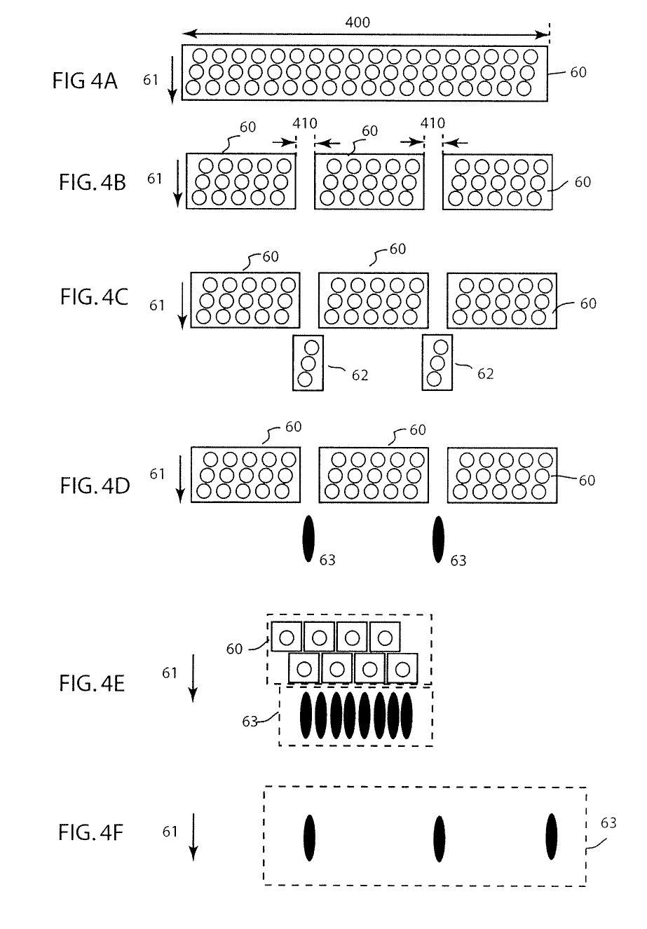

FIGS. 4A, 4B, 4C, 4D, 4E, and 4F are simplified diagrams showing the deposition/removal units 25 and/or 27 as parts of the system 200 for depositing one or more materials for photovoltaic cells according to certain embodiments of the present invention. These diagrams are merely examples, which should not unduly limit the scope of the claims. One of ordinary skill in the art would recognize many variations, alternatives, and modifications.

FIGS. 4A and 4B each show an array 60 of droplet sources. For example, the droplet sources that make up the array 60 are individually actuated, or can be grouped together and actuated as groups. In another example, the array 60 represent the one or more deposition/removal units 25, or the one or more deposition/removal units 27. According to an embodiment, the one or more deposition/removal units 25 includes the array 60 but do not include any removal component. According to another embodiment, the one or more deposition/removal units 27 include the array 60 but do not include any removal component.

In some embodiments, an array 60 of droplet sources includes rows of droplet sources, such as focused acoustic ejectors, inkjet nozzles, and/or spray nozzles. For example, the rows of the droplet sources are positioned slightly staggered from each other so as to provide a single pass, raster-free (if so desired) method of printing the desired pattern on a substrate, such as the substrate 24 or the substrate 43. In another example, the array 60 of droplet sources moves relative to the substrate in a direction 61.

As shown in FIG. 4A, each row of the array 60 of droplet sources is offset by a predetermined amount. For example, the array 60 is configured to make successive drops combine into a continuous sheet, even if each individual droplet source is larger and spaced further from its immediate neighbor than the resulting deposition pattern. In another example, the array 60, which forms the one or more deposition/removal units 25 or 27, has a width 400 that spans the entire width of the substrate 24 or 43. According to one embodiment, the array 60 moves relative to the substrate 24 or 43 in the direction 61, and allows for example a single-pass printing. According to another embodiment, such single-pass is beneficial over conventional printing techniques for printing symmetrical patterns in solar cells, and/or allows for a printing system highly suitable for solar cells. In yet another example, the array 60 has the width 400 that spans the width of one or several strips of solar cells rather than the entire panel. According to one embodiment, the array 60 is used to scan multiple times down the length of a panel to create the desired stripes of solar cells.

As shown in FIG. 4B, each row of the array 60 of droplet sources is offset by a predetermined amount with one or more columns 410 that does not have any activated droplet sources. According to one embodiment, this array 60 enables the printing of solar cells with both high speed and high-precision. For example, by eliminating or deactivating certain columns 410 of droplet sources, precise patterns and gaps that may be needed in solar cells can be created. In another example, these gap patterns 410 are incorporated in a low-cost, high-speed way into the basic design of the array 60 as shown FIG. 4A, because of the high degree of symmetry along one axis and repeated patterns that are often found in solar panels. In yet another example, the parts of the array 60 separated by the columns 410 forms different deposition/removal units and forms a single deposition/removal unit.

FIG. 4C shows arrays 60 and 62 of droplet sources. For example, the droplet sources that make up the array 60 are individually actuated, or can be grouped together and actuated as groups. In another example, the droplet sources that make up the array 62 are individually actuated, or can be grouped together and actuated as groups. In yet another example, the arrays 60 and 62 together represent the one or more deposition/removal units 25, or the one or more deposition/removal units 27. According to an embodiment, the one or more deposition/removal units 25 includes the arrays 60 and 62 but do not include any removal component. According to another embodiment, the one or more deposition/removal units 27 include the arrays 60 and 62 but do not include any removal component.

As shown in FIG. 4C, at least two arrays 60 and 62 of droplet sources are placed in close proximity with predetermined alignment to each other. For example, at least two different materials are deposited by the two arrays 60 and 62 of droplet sources. In one embodiment, the relative lateral position of these materials is determined, permanently and/or inexpensively, by the mechanical design of the arrays 60 and 62. In another example, the relative lateral position of these materials is adjusted across the length of the solar panel by dynamically shifting the array 62 with respect to the array 60, e.g., in the left/right direction.

The deposition/removal units 25 and/or 27 as shown in FIG. 4C have various advantage and/or applications. According to some embodiments, these units 25 and/or 27 enable very high speed printing and very precise relative alignment of the at least two constituent materials, such as inks. According to certain embodiments, these units 25 and/or 27 are useful in the simultaneous deposition of an active layer of a solar cell with a resist designed to keep the active layers in adjacent cells from bleeding into each other during the printing, drying, or annealing steps. According to some embodiments, these units 25 and/or 27 are useful where precise, high speed, low-cost alignment of two different chemicals is needed, for example, when an etchant for a lower layer (e.g., for a transparent conductor) and the ink for an upper coating layer (e.g., CdS in a CdS/CdTe cell) of a solar cell is applied simultaneously, obviating the need for alignment steps between the two layers. According to certain embodiments, the units 25 and/or 27 are useful for printing two layers that can be annealed simultaneously, for example, the window layer and the active layer of certain solar cells. For example, by changing the relative positions of the arrays 60 and 62, even if slightly, either with actuators or permanently by the design and construction of the units 25 and/or 27, different amounts of overlap or precise alignment between at least two layers can be created.

Alternatively, FIGS. 4D and 4E each show an array 60 of droplet sources and an array 63 of removal devices. For example, the array 63 of removal devices is an array of ablation devices. In another example, the combination of the arrays 60 and 63 represents the one or more deposition/removal units 25, or the one or more deposition/removal units 27. According to one embodiment, each of the one or more deposition/removal units 25 includes both a droplet source and a removal device. According to another embodiment, each of the one or more deposition/removal units 27 includes both a droplet source and a removal device.

As shown in FIG. 4D, the array 60 of droplet sources and the array 63 of removal devices are placed according to predetermined alignment. For example, the array 63 of removal devices includes ablation devices. In another example, the array 63 of removal devices include mechanical, laser, thermal, and/or chemical material removal devices.

The deposition/removal units 25 and/or 27 as shown in FIG. 4D have various advantages and/or applications. According to some embodiments, speed and/or precision in solar cell manufacturing is improved, and/or cost of solar cell manufacturing is lowered. According to certain embodiments, the removal devices of the array 63 are laser scribes, and the droplet sources of the array 60 are configured to print active-layer material (such as CdTe) for the solar cell. For example, the CdTe patterns are automatically and precisely aligned to the scribed lines in the transparent conductor (ITO) and window layers (CdS) beneath, simultaneously without additional steps. In another example, the processing steps which are automatically precisely aligned to each other can provide important cost savings and yield improvement in the solar cell fabrication.

As shown in FIG. 4E, the array 60 of droplet sources and the array 63 of removal devices are placed according to predetermined alignment. For example, the array 63 of removal devices includes ablation devices. In another example, the array 63 of removal devices include mechanical, laser, thermal, and/or chemical material removal devices.

The deposition/removal units 25 and/or 27 as shown in FIG. 4E have various advantages and/or applications. According to some embodiments, these deposition/removal units 25 and/or 27 can effectively correct for film imperfections that are detected by the feedback system 26. According to certain embodiments, the removal devices of the array 63 include individually addressable ablation devices, such as laser scribes, and the droplet sources of the array 60 include individually addressable ink jets, spray nozzles, and/or acoustic ejectors. For example, if any gap or thinness in the film is detected by the feedback system 26, one or more droplet sources of the array 60 are triggered to precisely deposit missing material. In another example, if the film has been determined to be too thick or deposited in an incorrect location by the feedback system 26, one or more ablation devices of array 63 are triggered to remove film in that specific location. In yet another example, film pinholes, shorts, mis-alignment, and/or non-uniformity can be corrected in the production line, simultaneously at high throughput and without additional processing steps.

Alternatively, FIG. 4F shows an array 63 of removal devices. For example, the array 63 of removal devices is an array of ablation devices. In another example, the array 63 represents the one or more deposition/removal units 25, or the one or more deposition/removal units 27. According to one embodiment, the one or more deposition/removal units 25 do not include any droplet source. According to another embodiment, the one or more deposition/removal units 27 do not include any droplet source.

As shown in FIG. 4F, the array 63 of removal devices are placed according to predetermined alignment. For example, the array 63 of removal devices includes ablation devices. In another example, the array 63 of removal devices include mechanical, laser, thermal, and/or chemical material removal devices.

The deposition/removal units 25 and/or 27 as shown in FIG. 4E have various advantages and/or applications. According to some embodiments, these deposition/removal units 25 and/or 27 can effectively cut films that are uniform across the module into segments for each solar cell on the module. According to certain embodiments, the removal devices of the array 63 include individually addressable ablation devices, such as laser scribes, and these ablation devices are aligned to the correct cell-cell spacing for the module. For example, a sufficient number of spaced ablation devices are arranged across the module, so that a single pass between the units 25 and/or 27 and the module is sufficient to cut a uniform film into a patterned film for solar cells, or to clean the edges and/or prevent electrical shorts between areas of a patterned film. In another example, such single pass is well suited for high throughput production.

As discussed above and further emphasized here, FIGS. 4A, 4B, 4C, 4D, 4E, and 4F are merely examples, which should not unduly limit the scope of the claims. One of ordinary skill in the art would recognize many variations, alternatives, and modifications. For example, the array 60, the array 62, and/or the array 63 are separated into one or more groups. In one embodiment, each group includes one or more droplet sources, and/or one or more removal devices. In another embodiment, each group deposits material with a width that is the same as a photovoltaic cell. For example, the width is 5 cm or less, or ranges from 0.5 cm to 2 cm. In another example, the length of the photovoltaic cell is 5 cm or more, 50 cm or more, or 200 cm or more. According to another embodiment, the array 60, the array 62, and/or the array 63 each include a sufficient number of droplet sources or removal devices so as to sufficiently cover the substrate 24 or 43. For example, the total width of the substrate 24 or 43 is 50 cm, or 100 cm, or 300 cm.

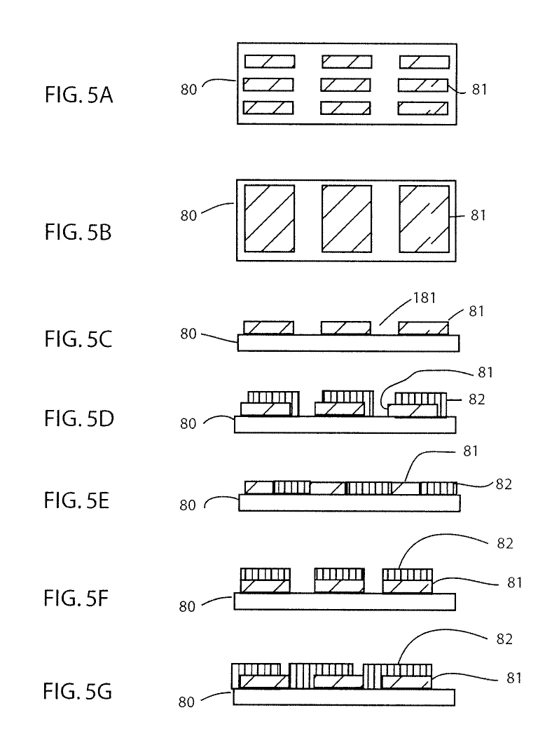

FIGS. 5A, 5B, 5C, 5D, 5E, 5F, and 5G are simplified diagrams showing one or more layers of one or more materials that formed by the system 200 for depositing one or more materials for photovoltaic cells according to certain embodiments of the present invention. These diagrams are merely examples, which should not unduly limit the scope of the claims. One of ordinary skill in the art would recognize many variations, alternatives, and modifications.

Specifically, FIGS. 5A and 5B illustrate top views and FIGS. 5C, 5D, 5E, 5F, and 5G illustrate side views of a variety of patterns for the one or more layers according to some embodiments of the present invention. For example, these patterns are used in the process of patterning one or more materials to make a photovoltaic cell.

In one embodiment, FIG. 5A shows a simplified top-down view of a two-dimensional array of patterns 81 on a substrate 80. In another embodiment, FIG. 5B shows a top-down view of a one-dimensional array of stripes 81 on the substrate 80. For example, the substrate 80 is the substrate 24 or 43. In another example, both the two-dimensional array of patterns 81 and the one-dimensional array of stripes 81 are useful in the fabrication of solar cells, and can be printed by the system 200 according to the method 150.

According to some embodiments, fabrication of solar cells includes printing or creation of a material layer with precise relative alignment to an underlying layer. For example, the thickness of patterns or stripes 81 ranges from 10 nm to 1 mm. In another example, the uniformity of the printed patterns or stripes 81 has less than 50% in thickness variation, or less than 5% in thickness variation. In yet another example, the pattern edge variation is less than 1 mm, less than 100 microns, or less than 10 microns.

Some examples of the types of patterns that can be formed by the system 200 using the method 150 are shown in FIGS. 5C, 5D, 5E, 5F, and 5G. These simplified diagrams show relative alignment of one layer to another according to some embodiments. Various combinations of the left or right edge alignments as shown in these diagrams can be fabricated by the system 200 using the method 150.

FIG. 5C shows a simple non-continuous pattern including stripes 81 containing material and stripes 181 without material. For example, the stripes 81 are the ones as shown in FIG. 5B. In another example, the pattern of FIG. 5C are useful for patterning decorative material or conductive front-contact (window layer) pads for solar cells or patterning the active layer on top of the window layer according to some embodiments.

Alternatively, the pattern in FIG. 5D shows a layer 82 is deposited to include a plurality of parts, which cover one edge (e.g., right-side) of the respective underlying stripes 81 as shown in FIG. 5B. Alternatively, the pattern of FIG. 5E shows a layers 82 is deposited to include a plurality of parts, which are disposed in between the stripes 81 as shown in FIG. 5B. For example, the pattern of FIG. 5E is useful in printing a resist between active regions of the solar cell to prevent spreading during printing, drying, annealing, or other subsequent processing steps, or to print insulating stripes that would allow for additional layers to be printed without shorting to the substrate in the solar cell. Alternatively, the pattern of FIG. 5F shows a layer 82 is deposited to include a plurality of parts, whose both edges are aligned to the edges of the respective stripes 81. For example, the pattern of FIG. 5F is useful for printing two layers which should be exactly aligned, such as the active layer and top contact material of solar cells.

According to certain embodiments, the alignments as shown in FIGS. 5C, 5D, 5E, and 5F can be combined as needed. One example is shown in FIG. 5G, where the overlap alignment of FIG. 5D is combined with the flush alignment of FIG. 5E.

According to some embodiments, the alignments as shown in FIGS. 5C, 5D, 5E, 5F, and 5G and their various combinations can be applied to both the two-dimensional array and the one-dimensional array on the substrate 80 as shown in FIGS. 5A and 5B respectively. For example, the extensions of the relative side view alignments in FIGS. 5C, 5D, 5E, 5F, and 5G can be applied to the relative alignments in both X and Y directions of the two-dimensional array of FIG. 5A, to the relative alignments in the one-dimensional array of FIG. 5B, or even to irregular, non-periodic patterns.

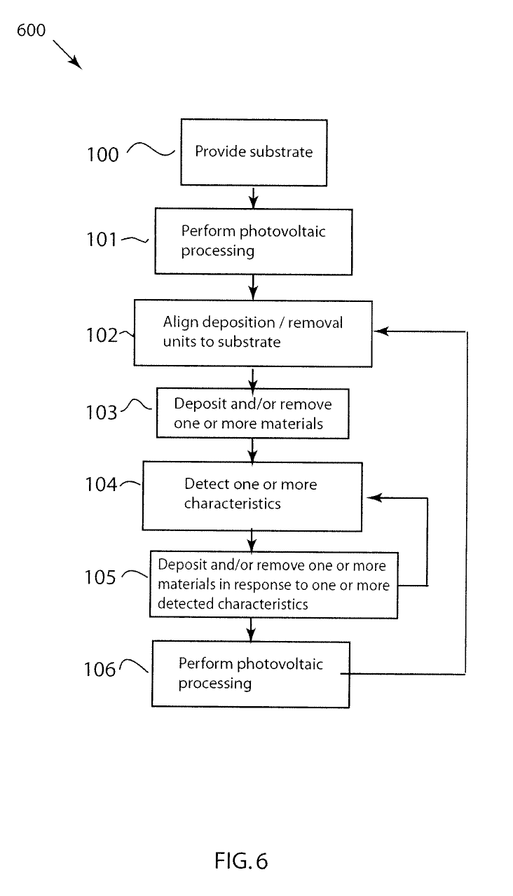

FIG. 6 is a simplified diagram showing a method for manufacturing a photovoltaic device according to one embodiment of the present invention. This diagram is merely an example, which should not unduly limit the scope of the claims. One of ordinary skill in the art would recognize many variations, alternatives, and modifications.

For example, the method 600 is used to manufacture a photovoltaic module with patterns formed by the system 200. In another example, the method 600 includes processes of the method 150. In yet another the photovoltaic device is a photovoltaic module. In yet another example, the photovoltaic device is a solar cell.

As discussed above, various embodiments of the present invention faun one or more patterned layers by depositing droplets in controlled locations, monitoring the resulting film, and if needed, depositing more material or removing some of the deposited material to achieve the predetermined film location and characteristics. To form a layer from a plurality of deposited droplets, the droplets contain a suspension of particles, such as 1 nm-10 microns in size, in a solvent or carrier fluid according to one embodiment. In another embodiment, the droplets contain chemical precursors that react to form the layer spontaneously under the influence of heat, light, and/or chemicals. In yet another embodiment, the droplets contain particles that can be melted or annealed together to form the film, particles that melt with the assistance of flux to form the film, particles that are sintered, and/or liquid metal or liquid polymer that solidifies to form the film.

After the droplets are deposited, whether in particle or precursor form, one or more material layers can be processed to achieve predetermined electrical or optical properties according to some embodiments. For example, the one or more material layers undergo annealing or sintering (in air or in a controlled atmosphere) at temperatures of 50-1500 degrees Celsius, doping, etching, scribing, or other forms of chemical, thermal and/or sonic treatments.

As shown in FIG. 6, the method 600 includes a process 100 for providing a substrate, a process 101 for performing photovoltaic processing, a process 102 for aligning deposition/removal units to the substrate, a process 103 for depositing and/or removing one or more materials, a process 104 for detecting one or more characteristics, a process 105 for depositing and/or removing one or more materials in response to one or more detected characteristics, and a process 106 for performing photovoltaic processing.

At the process 100, a substrate, such as the substrate 24, 43, or 80, is provided. At the process 101, one or more steps for fabricating a photovoltaic device is performed. For example, the one or more steps includes vacuum deposition, sputtering, chemical vapor deposition, and/or others.

At the process 102, one or more deposition/removal units are aligned to the substrate. For example, the one or more deposition/removal units are the units 25 or 27. In another example, the substrate is the substrate 24, 43, or 80, with or without one or more patterned or un-patterned films.

At the process 103, one or more materials are deposited onto and/or removed from the substrate. For example, the substrate is the substrate 24, 43, or 80, with or without one or more patterned or un-patterned films. In another example, the one or more deposition/removal units 25 or 27 remove undesired material from the printed films on the substrate, by, for example, laser ablation, mechanical, thermal, and/or chemical mechanisms. In yet another example, the one or more deposition/removal units 25 or 27 provides one or more droplets associated with the one or more desired materials and fauns a predetermined pattern.

According to one embodiment, the one or more droplets are loaded with particles that can form a film when the solvent evaporates. According to another embodiment, the droplets contain one or more chemical precursors that can form a film when the one or more precursors are in contact with one or more other chemicals, or with the substrate. For example, the substrate is heated or cooled. According to yet another embodiment, the droplets contain molten or dissolved metal and/or polymer, which solidifies upon contact with the substrate.

At the process 104, one or more characteristics are detected, for example, by the feedback system 26. For example, the process 104 is performed during and/or after the performance of the process 103. In another example, the one or more monitored characteristics are related to the deposited film. In yet another example, the one or more monitored characteristics are related to the deposition/removal units 25 or 27. According to an embodiment, the feedback system 26 detects nozzle clogging, ablation parameters, film thickness, film position, film uniformity, and/or other characteristics.

At the process 105, in response to the monitored characteristics, one or more materials are deposited onto and/or removed from the substrate. For example, the deposition/removal units 25 or 27 are used to deposit or ablate material in order to cure film detects. As shown in FIG. 6, the process 104 and the process 105 can be repeated one or more times, until the desired film properties are obtained.

At the process 106, one or more steps for fabricating a photovoltaic device is performed. For example, the one or more steps includes annealing the printed film to improve its properties. If more patterned films are desired, the processes 102, 103, 104, 105, and 106 are repeated one or more times. Also, at the process 106, module sealing and junction box mounting are performed in order to complete the fabrication of the photovoltaic device according to an embodiment.

As discussed above and further emphasized here, FIG. 6 is merely an example, which should not unduly limit the scope of the claims. One of ordinary skill in the art would recognize many variations, alternatives, and modifications. For example, a test substrate is run through the processes 102, 103, and 104, and the feedback system can record the quality of the resulting pattern, using an optical image or other measurements. In response, the feedback system 26 then adjust the process 103 based on the observation of the pattern on the test substrate while maintaining the calibration for a plurality of substrates before being re-calibrated according to certain embodiments. For example, the feedback system 26 may disable a malfunctioning printhead and continue printing the desired pattern by using other printheads to cover the area that would have been covered by the disabled printhead. Another example of calibration by the feedback system 26 would be to measure the optical characteristics of a deposited film on a test substrate and to change the flow rate of ink or gas to spray nozzles to improve film uniformity or match the desired thickness.

According to certain embodiments, the techniques outlined herein can be used to deposit a wide range of materials needed in the manufacturing process of a photovoltaic cell or module. For example, the ink and films are elements and/or compounds formed from (but not limited to): Ag, Cu, C, Cd, Te, Si, In, Ga, Se, S, Sn, Hg, Pb, Cl, Zn, Ti, N, O, and/or H. These inks can be used to print material layers of, for example, CdTe, CdS, Cadmium Stannate, ITO (Indium Tin Oxide), FTO, Carbon paste, Carbon nanotube films, CIGS, Mo, CIS (copper indium selenide), ZTO (Zinc Tin Oxide), silicon, spin-on glass, and polymers used in organic solar cells including P3HT, PCBM (fullerene derivative [6,6]-phenyl-C₆₁-butyric acid methyl ester), PEDOT-PSS (Poly(3,4-ethylenedioxythiophene) poly(styrenesulfonate)), PBTTT (Poly(2,5-bis(3-tetradecyll thiophen-2-yl)thieno[3,2-b]thiophene)), and/or TiO2 (titanium dioxide). These and other materials may be printed as particles in their elemental form, as particles in compound form, dissolved in solution, molten, as organometalics, as salts or in any other form that enables the resultant deposition of the desired material. In another example, the ink materials are solvents or carrier fluids (or particle laden solvents or carrier fluids) including but not limited to water, propylene glycol, polypropylene glycol, ethanol, methanol, glycerol, ethylene glycol, polyethylene glycol, or mixtures thereof. In yet another example, the ink may or may not contain surfactants, binders, or other additives that alter the surface tension, viscosity, surface forces, or other properties of the carrier fluid, solvent, or particles to be printed. These inks can also comprise fluxes, etchants, detergents, dopants, glues, epoxies, and other substances useful in the manufacturing of photovoltaic cells or modules.

According to some embodiments, printing of such material for manufacturing photovoltaic cells bypasses a number of time-consuming and costly steps, and makes possible new steps not used in conventional solar cell production techniques. For example, printing enables high-speed, low cost deposition of the various layers of a photovoltaic cell as well as the interconnects between those cells, forming the precisely aligned patterns important for a fully functioning large-scale solar panel at drastically reduced fabrication cost, with high speed, and with drastically reduced material waste. In another example, by moving to a non-vacuum environment (since acoustic printing does not require a vacuum environment), and with high material use efficiency, both capital and manufacturing costs for production of thin film photovoltaic modules are reduced. In yet another example, since acoustic printing is a non-contact printing method, films may be printed onto substrates without contact with the substrate and without damaging previous patterns already deposited on the substrate. In yet another example, printheads can be constructed with a dense array of droplet sources, allowing for high throughput operation in solar cell production.

According to certain embodiments, methods and systems for detecting film imperfections are provided with a feedback system that can rapidly send control signals to one or more sets of deposition/ablation units capable of correcting the imperfections with the film with high throughput. For example, imperfections of the film include poor edge definition, film pinholes, film thickness variation, and/or deposition in an incorrect location.

According to another embodiment, a method for forming one or more predetermined patterns on a substrate for making a photovoltaic device is provided. The method includes aligning at least a first droplet source with a substrate, dispensing one or more first droplets associated with one or more first materials from the first droplet source, and forming at least a first pattern of one or more second materials on the substrate by at least the first droplet source. Additionally, the method includes providing a first light beam incident on at least the first pattern, obtaining a first signal associated with the first pattern in response to the first light beam, processing information associated with the first signal, and determining one or more first characteristics of the first pattern based on at least information associated with the first signal. Moreover, the method includes processing information associated with the one or more first characteristics, and changing the first pattern to a second pattern by at least a pattern forming device. The pattern forming device including at least a second droplet source, at least a material removal device, or at least the second droplet source and the material removal device. For example, the method is implemented according to at least FIG. 1 and/or FIG. 6.

In yet another example, a photovoltaic device includes a photovoltaic cell, such as a solar cell. In yet another example, a photovoltaic device includes a photovoltaic module, such as a solar module. In yet another example, the first pattern is a uniform layer on the substrate, and the process for changing the first pattern to a second pattern by at least a pattern forming device includes changing the thickness of the uniform layer from a first thickness value to a second thickness value.

In another example, the process for dispensing one or more first droplets associated with one or more first materials includes dispensing the one or more first droplets associated with the one or more first materials from at least one selected from a group consisting of a nozzle and an ejector. In yet another example, the process for dispensing one or more first droplets associated with one or more first materials includes dispensing the one or more first droplets associated with the one or more first materials from a printhead.

In yet another example, the process for changing the first pattern to a second pattern by at least a pattern forming device includes changing the first pattern to the second pattern by at least one selected from a group consisting of an optical ablation device and a mechanical ablation device. In yet another example, the process for forming at least a first pattern of one or more second materials on the substrate by at least the first droplet source includes forming at least the first pattern associated with at least one characteristic corresponding to thickness of a layer on the substrate. In yet another example, the process for forming at least a first pattern of one or more second materials on the substrate by at least the first droplet source includes forming at least the first pattern including at least a first part and a second part. The first part includes a third part of a substrate surface of the substrate without any of the one or more second materials on the third part, and a second part includes the one or more second materials on a fourth part of the substrate surface.

In yet another example, the process for forming at least a first pattern of one or more second materials on the substrate and the process for changing the first pattern to a second pattern are performed by at least a same droplet source, the same droplet source being the first droplet source, the same droplet source being the second droplet source. In yet another example, the process for obtaining a first signal associated with the first pattern includes obtaining an optical signal or an electrical signal associated with the first pattern in response to the first light beam. In yet another example, the optical signal is a second light beam transmitted through at least the first pattern in response to the first light beam. In yet another example, the optical signal is a second light beam reflected from at least the first pattern in response to the first light beam. In yet another example, the electrical signal is a current as a function of a voltage, the current and the voltage being related to at least the first pattern.

In yet another example, the process for determining one or more first characteristics includes determining at least one selected from a group consisting of absorption, transmission, reflection, roughness, fluorescence, and imaging. In yet another example, the process for determining one or more first characteristics includes determining at least one selected from a group consisting of photovoltaic IV response and photoemission.

In yet another example, the method further includes providing a second light beam incident on at least the second pattern, obtaining a second signal associated with the second pattern in response to the second light beam, processing information associated with the second signal, determining one or more second characteristics of the second pattern based on at least information associated with the second signal, processing information associated with the one or more second characteristics, changing the second pattern to a third pattern by a second pattern forming device. In yet another example, the second pattern forming device includes at least a third droplet source, at least a second material removal device, or at least the third droplet source and the second material removal device. In yet another example, the process for changing the first pattern to a second pattern and the process for changing the second pattern to a third pattern are performed by a same pattern forming device.

In yet another example, the method further includes before performing the process for aligning at least a first droplet source with a substrate, performing one or more first fabrication processes for making a photovoltaic module, and after performing the process for changing the first pattern to a second pattern, performing one or more second fabrication processes for making the photovoltaic module.

In yet another example, the one or more second fabrication processes include sealing the photovoltaic module and mounting a junction box. In yet another example, the one or more first materials are the same as the one or more second materials. In yet another example, at least one of the one or more first materials is different from each of the one or more second materials. In yet another example, at least one of the one or more second materials is different from each of the one or more first materials.

According to yet another embodiment, a method for forming one or more predetermined patterns on a substrate for making a photovoltaic device is provided. The method includes aligning at least a first droplet source with a substrate, dispensing one or more droplets associated with one or more first materials from the first droplet source, and forming at least a first pattern of one or more second materials on the substrate by at least the first droplet source. Additionally, the method includes providing a light beam incident on at least the one or more droplets, obtaining a signal associated with the one or more droplets in response to the light beam, processing information associated with the signal, and determining one or more characteristics of the first pattern based on at least information associated with the signal. Moreover, the method includes processing information associated with the one or more characteristics, and changing the first pattern to a second pattern by a pattern forming device. The pattern forming device includes at least a second droplet source, at least a material removal device, or at least the second droplet source and the material removal device. For example, the method is implemented according to at least FIG. 1 and/or FIG. 6.

In another example, the process for forming at least a first pattern of one or more second materials on the substrate and the process for changing the first pattern to a second pattern are performed by at least a same droplet source. In yet another example, the one or more first materials are the same as the one or more second materials. In yet another example, at least one of the one or more first materials is different from each of the one or more second materials. In yet another example, at least one of the one or more second materials is different from each of the one or more first materials.

According to yet another embodiment, a system for forming one or more predetermined patterns on a substrate for making a photovoltaic device is provided. The system includes a positioning system configured to align at least a first droplet source with a substrate, at least the first droplet source configured to dispense one or more first droplets associated with one or more first materials and form at least a first pattern of one or more second materials on the substrate, and a light source configured to provide a first light beam incident on at least the first pattern. Additionally, the system includes a sensing device configured to obtain a first signal associated with the first pattern in response to the first light beam, and a control device configured to receive the first signal, process information associated with the first signal, determine one or more first characteristics of the first pattern based on at least information associated with the first signal, process information associated with the one or more first characteristics, and output a second signal based on at least information associated with the one or more first characteristics. Moreover, the system includes at least a first pattern forming device configured to receive the second signal and change the first pattern to a second pattern based on at least information associated with the second signal. The first pattern forming device includes at least a second droplet source, at least a material removal device, or at least the second droplet source and the material removal device. For example, the system is implemented according to at least FIG. 2, FIG. 3A, FIG. 3B, and/or FIG. 3C.

In another example, the control device includes a computer. In yet another example, the sensing device includes an optical detector. In yet another example, the sensing device includes an electrical measurement device configured to measure at least a current, a voltage, or the current and the voltage. In yet another example, the first droplet source is a part of a second pattern forming device. In yet another example, the first pattern forming device and the second pattern forming device are the same pattern forming device. In yet another example, the first pattern forming device and the second pattern forming device are two different pattern forming devices. In yet another example, the first droplet source includes at least one selected from a group consisting of a nozzle and an ejector. In yet another example, the ejector is an acoustic ejector. In yet another example, the nozzle is an inkjet nozzle or a spray nozzle. In yet another example, the first droplet source includes a printhead.

In yet another example, the first material removal device includes at least one selected from a group consisting of an optical ablation device and a mechanical ablation device. In yet another example, the first droplet source and the second droplet source are the same droplet source. In yet another example, the first droplet source and the second droplet source are two different droplet sources. In yet another example, the first signal is an optical signal or an electrical signal. In yet another example, the optical signal is a second light beam transmitted through at least the first pattern in response to the first light beam. In yet another example, the optical signal is a second light beam reflected from at least the first pattern in response to the first light beam. In yet another example, the electrical signal is a current as a function of a voltage, the current and the voltage being related to at least the first pattern.

In yet another example, the one or more first characteristics are associated with at least one selected from a group consisting of absorption, transmission, reflection, roughness, fluorescence, and imaging. In yet another example, the one or more first characteristics are associated with at least one selected from a group consisting of photovoltaic IV response and photoemission.

According to yet another embodiment, a system for forming one or more predetermined patterns on a substrate for making a photovoltaic device is provided. The system includes a positioning system configured to align at least a first droplet source with a substrate, at least the first droplet source configured to dispense one or more droplets associated with one or more first materials and form at least a first pattern of one or more second materials on the substrate, and a light source configured to provide a light beam incident on at least the one or more droplets. Additionally, the system includes a sensing device configured to obtain a first signal associated with the first pattern in response to the light beam, and a control device configured to receive the first signal, process information associated with the first signal, determine one or more characteristics of the first pattern based on at least information associated with the first signal, process information associated with the one or more characteristics, and output a second signal based on at least information associated with the one or more characteristics. Moreover, the system includes at least a pattern forming device configured to change the first pattern to a second pattern. The pattern forming device including at least a second droplet source, at least a material removal device, or at least the second droplet source and the material removal device. For example, the system is implemented according to at least FIG. 2, FIG. 3A, FIG. 3B, and/or FIG. 3C.

In another example, the first droplet source and the second droplet source are the same droplet source. In yet another example, the first droplet source and the second droplet source are two different droplet sources. In yet another example, the one or more first materials are the same as the one or more second materials. In yet another example, at least one of the one or more first materials is different from each of the one or more second materials. In yet another example, at least one of the one or more second materials is different from each of the one or more first materials.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A method for forming one or more predetermined patterns on a substrate for making a photovoltaic device, the method comprising:
aligning at least a first droplet source with a substrate;
dispensing one or more first droplets associated with one or more first materials from the first droplet source;
forming at least a first pattern of one or more second materials on the substrate by at least the first droplet source;
providing a first light beam incident on at least the first pattern;
obtaining a first signal associated with the first pattern in response to the first light beam;
processing information associated with the first signal;
determining one or more first characteristics of the first pattern based on at least information associated with the first signal;
processing information associated with the one or more first characteristics;
changing the first pattern to a second pattern by at least a pattern forming device, the pattern forming device including at least a second droplet source, at least a material removal device, or at least the second droplet source and the material removal device.

2. The method of claim 1 wherein the process for dispensing one or more first droplets associated with one or more first materials includes dispensing the one or more first droplets associated with the one or more first materials from at least one selected from a group consisting of a nozzle and an ejector.

3. The method of claim 1 wherein the process for dispensing one or more first droplets associated with one or more first materials includes dispensing the one or more first droplets associated with the one or more first materials from a printhead.

4. The method of claim 1 wherein the process for changing the first pattern to a second pattern by at least a pattern forming device includes changing the first pattern to the second pattern by at least one selected from a group consisting of an optical ablation device and a mechanical ablation device.

5. The method of claim 1 wherein the process for forming at least a first pattern of one or more second materials on the substrate by at least the first droplet source includes forming at least the first pattern associated with at least one characteristic corresponding to thickness of a layer on the substrate.

6. The method of claim 1 wherein the process for forming at least a first pattern of one or more second materials on the substrate by at least the first droplet source includes forming at least the first pattern including at least a first part and a second part, the first part including a third part of a substrate surface of the substrate without any of the one or more second materials on the third part, a second part including the one or more second materials on a fourth part of the substrate surface.

7. The method of claim 1 wherein the process for forming at least a first pattern of one or more second materials on the substrate and the process for changing the first pattern to a second pattern are performed by at least a same droplet source, the same droplet source being the first droplet source, the same droplet source being the second droplet source.

8. The method of claim 1 wherein the process for obtaining a first signal associated with the first pattern includes obtaining an optical signal or an electrical signal associated with the first pattern in response to the first light beam.

9. The method of claim 8 wherein the optical signal is a second light beam transmitted through at least the first pattern in response to the first light beam.

10. The method of claim 8 wherein the optical signal is a second light beam reflected from at least the first pattern in response to the first light beam.

11. The method of claim 8 wherein the electrical signal is a current as a function of a voltage, the current and the voltage being related to at least the first pattern.

12. The method of claim 1 wherein the process for determining one or more first characteristics includes determining at least one selected from a group consisting of absorption, transmission, reflection, roughness, fluorescence, and imaging.

13. The method of claim 1 wherein the process for determining one or more first characteristics includes determining at least one selected from a group consisting of photovoltaic IV response and photoemission.

14. The method of claim 1, and further comprising:
providing a second light beam incident on at least the second pattern;
obtaining a second signal associated with the second pattern in response to the second light beam;
processing information associated with the second signal;
determining one or more second characteristics of the second pattern based on at least information associated with the second signal;
processing information associated with the one or more second characteristics;
changing the second pattern to a third pattern by a second pattern forming device, the second pattern forming device including at least a third droplet source, at least a second material removal device, or at least the third droplet source and the second material removal device.

15. The method of claim 14 wherein the process for changing the first pattern to a second pattern and the process for changing the second pattern to a third pattern are performed by a same pattern forming device.

16. The method of claim 1, and further comprising:
before performing the process for aligning at least a first droplet source with a substrate, performing one or more first fabrication processes for making a photovoltaic module;
after performing the process for changing the first pattern to a second pattern, performing one or more second fabrication processes for making the photovoltaic module.

17. The method of claim 16 wherein the one or more second fabrication processes include:
sealing the photovoltaic module; and
mounting a junction box.

18. The method of claim 1 wherein the one or more first materials are the same as the one or more second materials.

19. The method of claim 1 wherein at least one of the one or more first materials is different from each of the one or more second materials.

20. The method of claim 1 wherein at least one of the one or more second materials is different from each of the one or more first materials.

21. A method for forming one or more predetermined patterns on a substrate for making a photovoltaic device, the method comprising:
aligning at least a first droplet source with a substrate;
dispensing one or more droplets associated with one or more first materials from the first droplet source;
forming at least a first pattern of one or more second materials on the substrate by at least the first droplet source;
providing a light beam incident on at least the one or more droplets;
obtaining a signal associated with the one or more droplets in response to the light beam;
processing information associated with the signal;
determining one or more characteristics of the first pattern based on at least information associated with the signal;
processing information associated with the one or more characteristics;
changing the first pattern to a second pattern by a pattern forming device, the pattern forming device including at least a second droplet source, at least a material removal device, or at least the second droplet source and the material removal device.

22. The method of claim 21 wherein the process for forming at least a first pattern of one or more second materials on the substrate and the process for changing the first pattern to a second pattern are performed by at least a same droplet source.

23. The method of claim 21 wherein the one or more first materials are the same as the one or more second materials.

24. The method of claim 21 wherein at least one of the one or more first materials is different from each of the one or more second materials.

25. The method of claim 21 wherein at least one of the one or more second materials is different from each of the one or more first materials.

26. A system for forming one or more predetermined patterns on a substrate for making a photovoltaic device, the system comprising:
a positioning system configured to align at least a first droplet source with a substrate;
at least the first droplet source configured to dispense one or more first droplets associated with one or more first materials and form at least a first pattern of one or more second materials on the substrate;
a light source configured to provide a first light beam incident on at least the first pattern;
a sensing device configured to obtain a first signal associated with the first pattern in response to the first light beam;
a control device configured to receive the first signal, process information associated with the first signal, determine one or more first characteristics of the first pattern based on at least information associated with the first signal, process information associated with the one or more first characteristics, and output a second signal based on at least information associated with the one or more first characteristics;
at least a first pattern forming device configured to receive the second signal and change the first pattern to a second pattern based on at least information associated with the second signal, the first pattern forming device including at least a second droplet source, at least a material removal device, or at least the second droplet source and the material removal device.

27. The system of claim 26 wherein the control device includes a computer.

28. The system of claim 26 wherein the sensing device includes an optical detector.

29. The system of claim 26 wherein the sensing device includes an electrical measurement device configured to measure at least a current, a voltage, or the current and the voltage.

30. The system of claim 26 wherein the first droplet source is a part of a second pattern forming device.

31. The system of claim 30 wherein the first pattern forming device and the second pattern forming device are the same pattern forming device.

32. The system of claim 30 wherein the first pattern forming device and the second pattern forming device are two different pattern forming devices.

33. The system of claim 30 wherein the first droplet source includes at least one selected from a group consisting of a nozzle and an ejector.

34. The system of claim 33 wherein the ejector is an acoustic ejector.

35. The system of claim 33 where the nozzle is an inkjet nozzle or a spray nozzle.

36. The system of claim 30 wherein the first droplet source includes a printhead.

37. The system of claim 30 wherein the first material removal device includes at least one selected from a group consisting of an optical ablation device and a mechanical ablation device.

38. The system of claim 30 wherein the first droplet source and the second droplet source are the same droplet source.

39. The system of claim 30 wherein the first droplet source and the second droplet source are two different droplet sources.

40. The system of claim 30 wherein the first signal is an optical signal or an electrical signal.

41. The system of claim 40 wherein the optical signal is a second light beam transmitted through at least the first pattern in response to the first light beam.

42. The system of claim 40 wherein the optical signal is a second light beam reflected from at least the first pattern in response to the first light beam.

43. The system of claim 40 wherein the electrical signal is a current as a function of a voltage, the current and the voltage being related to at least the first pattern.

44. The system of claim 26 wherein the one or more first characteristics are associated with at least one selected from a group consisting of absorption, transmission, reflection, roughness, fluorescence, and imaging.

45. The system of claim 26 wherein the one or more first characteristics are associated with at least one selected from a group consisting of photovoltaic IV response and photoemission.

46. A system for forming one or more predetermined patterns on a substrate for making a photovoltaic device, the system comprising:
a positioning system configured to align at least a first droplet source with a substrate;
at least the first droplet source configured to dispense one or more droplets associated with one or more first materials and form at least a first pattern of one or more second materials on the substrate;
a light source configured to provide a light beam incident on at least the one or more droplets;
a sensing device configured to obtain a first signal associated with the first pattern in response to the light beam;
a control device configured to receive the first signal, process information associated with the first signal, determine one or more characteristics of the first pattern based on at least information associated with the first signal, process information associated with the one or more characteristics, and output a second signal based on at least information associated with the one or more characteristics;
at least a pattern forming device configured to change the first pattern to a second pattern, the pattern forming device including at least a second droplet source, at least a material removal device, or at least the second droplet source and the material removal device.

47. The system of claim 46 wherein the first droplet source and the second droplet source are the same droplet source.

48. The system of claim 46 wherein the first droplet source and the second droplet source are two different droplet sources.

49. The system of claim 46 wherein the one or more first materials are the same as the one or more second materials.

50. The system of claim 46 wherein at least one of the one or more first materials is different from each of the one or more second materials.

51. The system of claim 46 wherein at least one of the one or more second materials is different from each of the one or more first materials.
